(19) United States
(12) Patent Application Publication
(10) Pub. No.: US 2003/0124818 A1
(43) Pub. Date: Jul. 3, 2003

(54) Method and apparatus for forming silicon containing films

(75) Inventors: Lee Luo, Fremont, CA (US); Ramaseshan Suryanarayanan Iyer, Santa Clara, CA (US); Shulin Wang, Campbell, CA (US); Aihau Chen, San Jose, CA (US); Paul Meissner, San Jose, CA (US)

Correspondence Address: APPLIED MATERIALS, INC., PATENT COUNSEL, LEGAL AFFAIRS DEPARTMENT, P.O. BOX 450A, SANTA CLARA, CA, 95052, US

(73) Assignee: APPLIED MATERIALS, INC.

(21) Appl. No.: 10/040,583

(22) Filed: Dec. 28, 2001

(51) Int. Cl. C30B 1/00; H01L 21/20; H01L 21/36; H01L 21/31; H01L 21/469

(52) U.S. Cl. 438/482; 438/486; 438/488

(57) ABSTRACT

The present invention describes a method and apparatus for forming a uniform silicon containing film in a single wafer reactor. According to the present invention, a silicon containing film is deposited in a resistively heated single wafer chamber utilizing a process gas having a silicon source gas and which provides an activation energy less than 0.5 eV at a temperature between 750° C.-550° C.

### BACKGROUND OF THE INVENTION

1. Field of the Invention

The present invention relates to the field of semiconductor manufacturing and more specifically to a method and apparatus for depositing uniform silicon containing films in a single wafer thermal chemical vapor deposition apparatus.

2. Discussion of Related Art

In order to fabricate semiconductor integrated circuits, multiple layers of silicon containing films, such as amorphous silicon, polysilicon, silicon nitride, silicon oxide and silicon oxynitride, etc. are deposited onto a semiconductor wafer in order to form active devices, such as transistors and capacitors as well as to form and isolate interconnects for the active devices. Silicon containing films have typically been formed by thermal chemical vapor deposition in batch type furnaces where multiple wafers, approximately 50, are processed at a single time. Batch type furnaces typically operate at very low pressures of less than 300 millitorr in order to minimize any gas depletion effects with an isothermal temperature environment. Operating at low pressures forms very uniform films across a wafer, however, the films are formed at very low deposition rates requiring long process times to deposit films.

Industry trend has moved towards single wafer chemical vapor deposition machines in order to improve manufacturing and integration. In order to deposit silicon containing films in single wafer reactor in an economically competitive manner with respect to batch type furnaces, single wafer processes must deposit the silicon containing film at a much higher deposition rate, at least 500 Å per minute and typically at least 1000 Å per minute. In order to deposit silicon containing films at a faster deposition rate, higher deposition pressures, greater than 1.0 torr and typically greater than 50 torr are used. Unfortunately using high deposition pressures to achieve high deposition rates together with high temperature sensitivity of the deposition process lead to non-uniformity of the film thickness and composition. This non-uniformity of film thickness and composition is expected to increase as wafer migrate from 200 millimeter diameters to 300 millimeters and beyond.

Thus, what is desired is a method and apparatus for improving film thickness and composition uniformity in a single wafer thermal chemical vapor deposition apparatus.

### SUMMARY OF THE INVENTION

The present invention describes a method and apparatus for forming a uniform silicon containing film in a single wafer reactor. According to the present invention, a silicon containing film is deposited in a resistively heated single wafer chamber utilizing a process gas having a silicon source gas and which provides an activation energy less than 0.5 eV at a temperature between 750° C.-550° C.

### BRIEF DESCRIPTION OF THE DRAWINGS

FIG. 1 is an illustration of a cross-sectional side view of a processing chamber comprising a resistive heater in a wafer process position which can be used to form the silicon containing films of the present invention.

FIG. 2 is an illustration of a similar cross-sectional side view as in FIG. 1 in a wafer separate position.

FIG. 3 shows an illustration of similar cross-sectional side view as in FIG. 1 in a wafer load position.

FIG. 4 is an illustration showing the non-uniform temperature distribution of a wafer.

FIG. 5 shows an illustration of a method of forming a bi-layer silicon film.

FIGS. 6A-6D illustrate a method of fabricating a transistor having a bi-layer silicon gate electrode.

FIG. 7 is a graph which illustrates how the deposition rate of a polycrystalline silicon film varies for different temperatures when using disilane and silane.

FIG. 8A is a graph which illustrates how the value of (n) varies for films formed with different NH₃/Si₂H₆ ratios at different temperature.

FIG. 8B illustrates how the extinction coefficient (k) varies for silicon nitride films formed at different temperatures, pressures, and Si₂H₆ flow rates.

FIG. 8C illustrates how the deposition rate of a silicon nitride film varies for different temperatures, pressures and disilane flow rates.

FIG. 8D illustrates how deposition rate of silicon nitride varies for different silicon gas flow rates.

FIG. 8E is a graph which illustrates how the deposition rate of a silicon nitride film varies for different temperatures when using disilane.

FIGS. 9A-9F illustrate a method of patterning a film utilizing a silicon nitride film formed from disilane as hard mask and as an anti-reflective coating.

FIGS. 10A-10D illustrate a method of forming a composite film stack of different silicon containing films at substantially the same deposition temperature.

### DETAILED DESCRIPTION OF THE PRESENT INVENTION

In the following description for the purposes of explanation numerous specific details are set forth in order to provide a thorough understanding of the present invention. It will be evident, however, to one skilled in the art that the present invention may be practiced without these specific details. In certain instances, specific apparatus structures and methods have not been described so as not to obscure the present invention.

The present invention is a method and apparatus for forming a uniform silicon containing film, such as amorphous or polycrystalline silicon or silicon nitride in a low pressure single wafer chemical vapor deposition (LPCVD) reactor. According to the present invention a silicon containing film is deposited with a process gas mix which has a silicon source gas and which provides a low reaction activation energy of less than 0.5 eV, preferably less than 0.3 eV and ideally less than 0.2 eV when depositing a silicon containing film by thermal chemical vapor deposition at a temperature less than 750° C. and above 550° C. In a preferred embodiment of the present invention, disilane (Si₂H₆) is used as the silicon source gas to deposit the silicon containing film. Although disilane (Si₂H₆) is the preferred silicon source gas, other silicon source gas, such as Si₃H₈, may be utilized as long as they produce a process gas mix which provides a reaction activation energy of less than 0.5 eV at a temperature less than 750° C.

By utilizing a process gas mix having a silicon source gas and which provides a low reaction activation energy, the silicon source gas decomposes faster and more efficiently to provide silicon atoms. Thermal chemical vapor deposition processes utilizing process gas mix which provide low reaction activation energies are less temperature sensitive than are deposition processes which utilize deposition gases having high reaction activation energy such as process gases utilizing silane (SiH₄). Because process gas mixes which provides a low reaction activation energy are less sensitive to temperature variation, they can be used to produce extremely uniform thickness films across the surface of the wafer even when the wafer is non-uniformly heated. By utilizing process gas mix which provides a low reaction activation energy, a silicon containing film can be formed by thermal chemical vapor deposition across the surface of the wafer with a thickness uniformity which is less than 1% and ideally less than 0.5% even when the wafer is heated such that it has a greater than 10° C. temperature variation across its surface during deposition. The use of a process gas mix having a silicon source gas and which provides a low reaction activation energy enables one to form uniform silicon containing films at high deposition rates, between 1000-3000 Å per minute, with excellent wafer to wafer repeatability. Additionally, by using a process gas mix which provides a low reaction activation energy, uniform films can be formed at relatively lower temperatures than process gas mix with high reaction activation energies. A process gas mix having a silicon source gas and which provides a low reaction activation energy can be used to form a wide variety of silicon containing films, such as but not limited to doped or undoped amorphous and polycrystalline silicon films, doped or undoped amorphous and polycrystalline silicon alloy films, such as silicon germanium (SiₓGe_{y}), silicon nitride films, silicon oxynitride films, and silicon oxide films.

Additionally, because process gas mixes which provide low reaction activation energies are less temperature dependent, a single deposition temperature can be used to deposit each layer of a composite film stack comprising multiple layers of different silicon containing films. For example, in the fabrication of modern gate electrodes, a composite film stack comprising a lower silicon film, a middle silicon germanium alloy film, and a top silicon film are sometimes desired. The ability to deposit each film of the stack at the same deposition temperature dramatically improves wafer throughput. This is especially useful in cases where the temperature of the wafer is maintained and controlled by means, such as a resistive heater, which cannot reliably change temperature rapidly (i.e, changes temperatures at a rate of less than 1° C. per second).

In an embodiment of the present invention, a process gas mix having a silicon source gas and which provides a low reaction activation energy is used to form a silicon nitride film. By utilizing a process gas mix having a silicon source gas and a low reaction activation energy enables the formation of a silicon nitride film having precise control over the films composition and properties. For example, by utilizing a process gas mix which provides a low reaction activation energy, the composition of the film can be tuned to produce a wide range of refractive indexes for the film. By being able to produce a silicon nitride film with varying refractive indexes, the silicon nitride films can be used as anti-reflective coating at various steps in an integrated circuit manufacturing process. This is especially useful when the silicon nitride film is already providing a separate function, such as a hard mask, in the fabrication of the integrated circuit. In this way, the silicon nitride film can provide dual functions as a hard mask as well as an anti-reflective coating (ARC). This can dramatically decrease integrated circuit manufacturing complexity, cost and time by removing the need for a separate ARC layer.

Other advantages of utilizing a process gas mix having a silicon source gas and which provides a low reaction activation energy during the formation of a silicon containing films by thermal chemical vapor deposition will be evident from the disclosure.

Apparatus

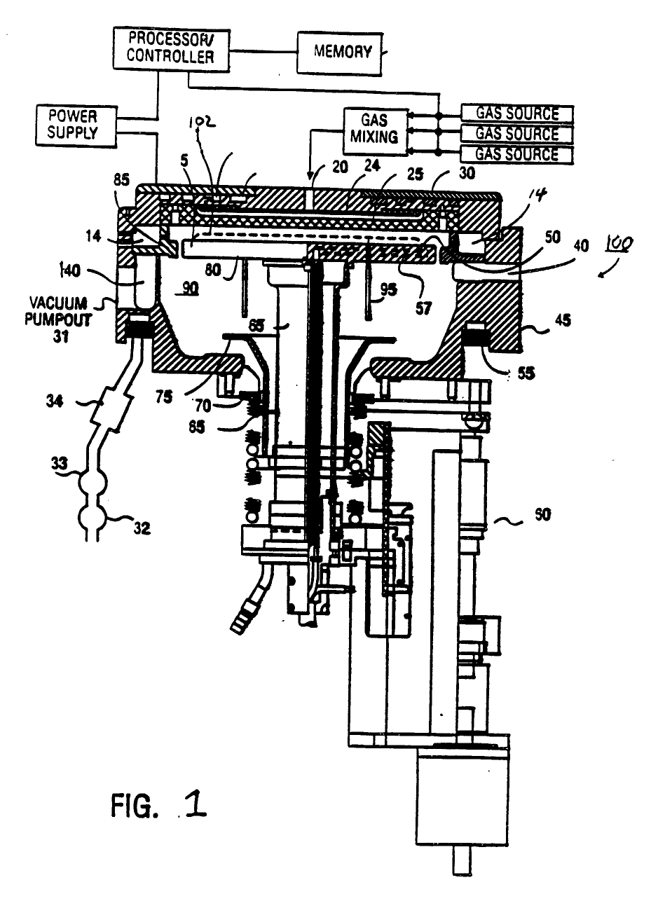

The method of forming a silicon containing film in accordance with the present invention, preferably occurs in a resistively heated single wafer low pressure chemical vapor deposition (LPCVD) apparatus such as shown in FIGS. 1-3. It is to be appreciated that other single wafer LPCVD chambers having similar functionality can be used.

Referring to the drawings, a low-pressure chemical vapor deposition (LPCVD) chamber is described. FIGS. 1-3 each show cross-sectional views of one type of reactor such as a resistive reactor used to practice the invention. FIGS. 1-3 each show cross-sectional views of a chamber through two different cross-sections, each cross-section representing a view through approximately one-half of the chamber.

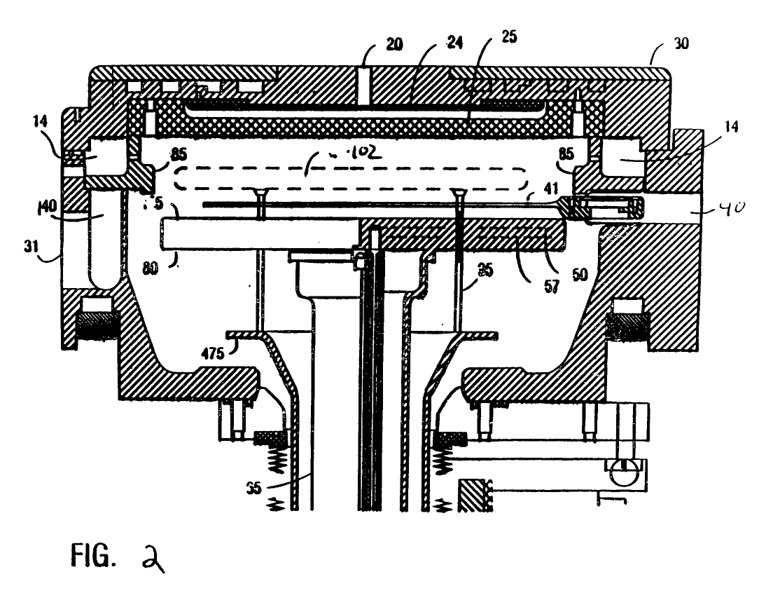

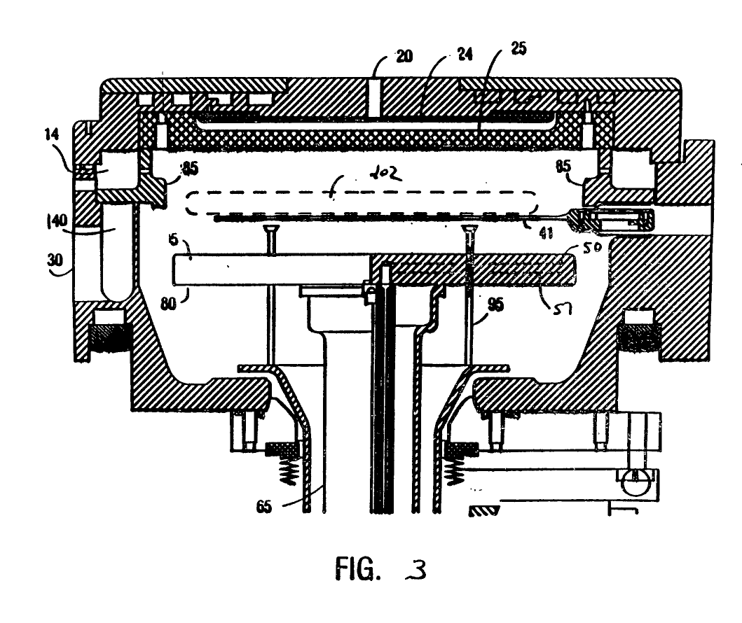

The LPCVD chamber 100 illustrated in FIGS. 1-3 is constructed of materials such that, in this embodiment, a pressure of less than or equal to 500 Torr can be maintained. For the purpose of illustration, a chamber of approximately in the range of 5-6 liters is described. FIG. 1 illustrates the inside of process chamber body 45 in a “wafer-process” position. FIG. 2 shows the same view of the chamber in a “wafer-separate” position. FIG. 3 shows the same cross-sectional side view of the chamber in a “wafer-load” position. In each case, a wafer 102 is indicated in dashed lines to indicate its location in the chamber.

FIGS. 1-3 show chamber body 45 that defines reaction chamber 90 in which the thermal decomposition of a process gas or gases takes place to form a film on a wafer (e.g., a CVD reaction). Chamber body 45 is constructed, in one embodiment, of aluminum and has passages 55 for water to be pumped therethrough to cool chamber 45 (e.g., a “cold wall” reaction chamber). Resident in chamber 90 is resistive heater 80 including, in this view, susceptor 5 supported by shaft 65. Susceptor 5 has a surface area sufficient to support a substrate such as a semiconductor wafer 500 (shown in dashed lines).

Process gas enters otherwise sealed chamber 90 through gas distribution port 20 in a top surface of chamber lid 30 of chamber body 45. The process gas then goes through blocker plate 25 to distribute the gas about an area consistent with the surface area of a wafer. Thereafter, the process gas is distributed through perforated face plate 25 located, in this view, above resistive heater 80 and coupled to chamber lid 30 inside chamber 90. One objective of the combination of blocker plate 24 with face plate 25 in this embodiment is to create a uniform distribution of process gas at the substrate, e.g., wafer.

A substrate 102, such as a wafer, is placed in chamber 90 on susceptor 5 of heater 80 through entry port 40 in a side portion of chamber body 45. To accommodate a wafer for processing, heater 80 is lowered so that the surface of susceptor 5 is below entry port 40 as shown in FIG. 3. Typically by a robotic transfer mechanism, a wafer is loaded by way of, for example, a transfer blade 41 into chamber 90 onto the superior surface of susceptor. Once loaded, entry 40 is sealed and heater 80 is advance in a superior (e.g., upward) direction toward face plate 25 by lifter assembly 60 that is, for example, a step motor. The advancement stops when the wafer 102 is a short distance (e.g., 400-700 mils) from face plate 25 (see FIG. 1). In the wafer-process position, chamber 90 is effectively divided into two zones, a first zone above the superior surface of susceptor 5 and a second zone below the inferior surface of susceptor 5. It is generally desirable to confine film formation to the first zone.

At this point, process gas controlled by a gas panel flows into chamber 90 through gas distribution port 20, through blocker plate 24 and perforated face plate 25. Process gas thermally decomposes to form a film on the wafer. At the same time, an inert bottom-purge gas, e.g., nitrogen, is introduced into the second chamber zone to inhibit film formation in that zone. In a pressure controlled system, the pressure in chamber 90 is established and maintained by a pressure regulator or regulators coupled to chamber 90. In one embodiment, for example, the pressure is established and maintained by baratron pressure regulator(s) coupled to chamber body 45 as known in the art.

Residual process gas is pumped from chamber 90 through pumping plate 85 to a collection vessel at a side of chamber body 45 (vacuum pumpout 31). Pumping plate 85 creates two flow regions resulting in a gas flow pattern that creates a uniform silicon layer on a substrate.

Pump 32 disposed exterior to apparatus provides vacuum pressure within pumping channel 140 (below channel 14 in FIGS. 1-3) to draw both the process and purge gases out of the chamber 90 through vacuum pump-out 31. The gas is discharged from chamber 90 along a discharge conduit 33. The flow rate of the discharge gas through channel 140 is preferably controlled by a throttle valve 34 disposed along conduit 33. The pressure within processing chamber 90 is monitored with sensors (not shown) and controlled by varying the cross-sectional area of conduit 33 with throttle valve 34. Preferably, a controller or processor receives signals from the sensors that indicate the chamber pressure and adjusts throttle valve 34 accordingly to maintain the desired pressure within chamber 90. A suitable throttle valve for use with the present invention is described in U.S. Pat. No. 5,000,225 issued to Murdoch and assigned to Applied Materials, Inc., the complete disclosure by which is incorporated herein by reference.

Once wafer processing is complete, chamber 90 may be purged, for example, with an inert gas, such as nitrogen. After processing and purging, heater 80 is advanced in an inferior direction (e.g., lowered) by lifter assembly 60 to the position shown in FIG. 2. As heater 80 is moved, lift pins 95, having an end extending through openings or throughbores in a surface of susceptor 5 and a second end extending in a cantilevered fashion from an inferior (e.g., lower) surface of susceptor 5, contact lift plate 75 positioned at the base of chamber 90. As is illustrated in FIG. 2, in one embodiment, at the point, lift plate 75 remains at a wafer-process position (i.e., the same position the plate was in FIG. 1). As heater 80 continues to move in an inferior direction through the action of assembly 60, lift pins 95 remain stationary and ultimately extend above the susceptor or top surface of susceptor 5 to separate a processed wafer from the surface of susceptor 5. The surface of susceptor 5 is moved to a position below opening 40.

Once a processed wafer is separated from the surface of susceptor 5, transfer blade 41 of a robotic mechanism is inserted through opening 40 beneath the heads of lift pins 95 and a wafer supported by the lift pins. Next, lifter assembly 60 inferiorly moves (e.g., lowers) heater 80 and lifts plate 75 to a “wafer load” position. By moving lift plates 75 in an inferior direction, lift pins 95 are also moved in an inferior direction, until the surface of the processed wafer contacts the transfer blade. The processed wafer is then removed through entry port 40 by, for example, a robotic transfer mechanism that removes the wafer and transfers the wafer to the next processing step. A second wafer may then be loaded into chamber 90. The steps described above are generally reversed to bring the wafer into a process position. A detailed description of one suitable lifter assembly 60 is described in U.S. Pat. No. 5,772,773, assigned to Applied Materials, Inc. of Santa Clara, Calif.

In a high temperature operation, such as LPCVD processing to form a polycrystalline silicon film, the heater temperature inside chamber 90 can be as high as 750° C. or more. Accordingly, the exposed components in chamber 90 must be compatible with such high temperature processing. Such materials should also be compatible with such high temperature processing. Such materials should also be compatible with the process gases and other chemicals, such as cleaning chemicals (e.g., NF₃) that may be introduced into chamber 90. Exposed surfaces of heater 80 may be comprised of a variety of materials provided that the materials are compatible with the process. For example, susceptor 5 and shaft 65 of heater 80 may be comprised of similar aluminum nitride material. Alternatively, the surface of susceptor 5 may be comprised of high thermally conductive aluminum nitride materials (on the order of 95% purity with a thermal conductivity from 140 W/mK) while shaft 65 is comprised of a lower thermally conductive aluminum nitride. Susceptor 5 of heater 80 is typically bonded to shaft 65 through diffusion bonding or brazing as such coupling will similarly withstand the environment of chamber 90.

FIG. 1 also shows a cross-section of a portion of heater 80, including a cross-section of the body of susceptor 5 and a cross-section of shaft 65. In this illustration, FIG. 1 shows the body of susceptor 5 having two heating elements formed therein, first heating element 50 and second heating element 57. Each heating element (e.g., heating element 50 and heating element 57) is made of a material with thermal expansion properties similar to the material of the susceptor. A suitable material includes molybdenum (Mo). Each heating element includes a thin layer of molybdenum material in a coiled configuration.

In FIG. 1, second heating element 57 is formed in a plane of the body of susceptor 5 that is located inferior (relative to the surface of susceptor in the figure) to first heating element 50. First heating element 50 and second heating element 57 are separately coupled to power terminals. The power terminals extend in an inferior direction as conductive leads through a longitudinally extending opening through shaft 65 to a power source that supplies the requisite energy to heat the surface of susceptor 5. Also of note in the cross-section of heater 80 as shown in FIG. 1 is the presence of thermocouple 70. Thermocouple 70 extends through the longitudinally extending opening through shaft 65 to a point just below the superior or top surface of susceptor 5.

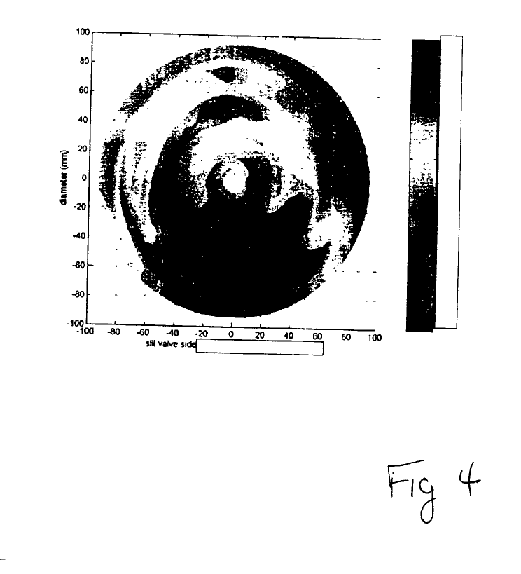

FIG. 4 is an illustration of the temperature distribution of a wafer placed on susceptor 5 and heated by ceramic heater 80. Different shades in FIG. 4 represent different temperatures. As evident from FIG. 4, heater 80 produces a non-uniform temperature distribution across the surface of the wafer. Heater 80 can create a temperature distribution of greater than 5° C. and sometimes greater than 10° C. across the surface of a 200 millimeter wafer. Additionally, as also shown in FIG. 4, heater 80 produce asymmetric heating of the wafer. The variation and temperature uniformity and asymmetry also varies from heater to heater. These non-uniformities and asymmetries of heat distribution with heater 80 are compounded for larger heater necessary to heat 300 millimeter wafers. Accordingly, in order to be able to form highly uniformed silicon containing films across a wafer heated by heater 80, Applicant's utilize a process gas mix having silicon source gas and which provides a low reaction activation energy, so that the deposition process is less temperature sensitive so that highly uniform films can be formed over the wafer.

Additionally, it is to be noted that because heater 80 is a resistive ceramic heater, it is unable to quickly change temperatures uniformly. Heater 80 typically can only uniformly change temperature at a rate of approximately less than 1.0° C. per second.

Silicon Film Formation

In an embodiment of the present invention, a process gas mix having a silicon source gas and which provides a low reaction activation energy is used in the formation of an amorphous or polycrystalline silicon film. In a preferred embodiment of the present invention, disilane (Si₂H₆) is used as the silicon source gas to form an amorphous or polycrystalline silicon film. By utilizing disilane, a uniform doped or undoped silicon film can be formed over the surface of a wafer even when the wafer is heated non-uniformly and asymmetrically by resistively heated ceramic heater 80. The amorphous or polycrystalline silicon film can be undoped or insitu doped during deposition.

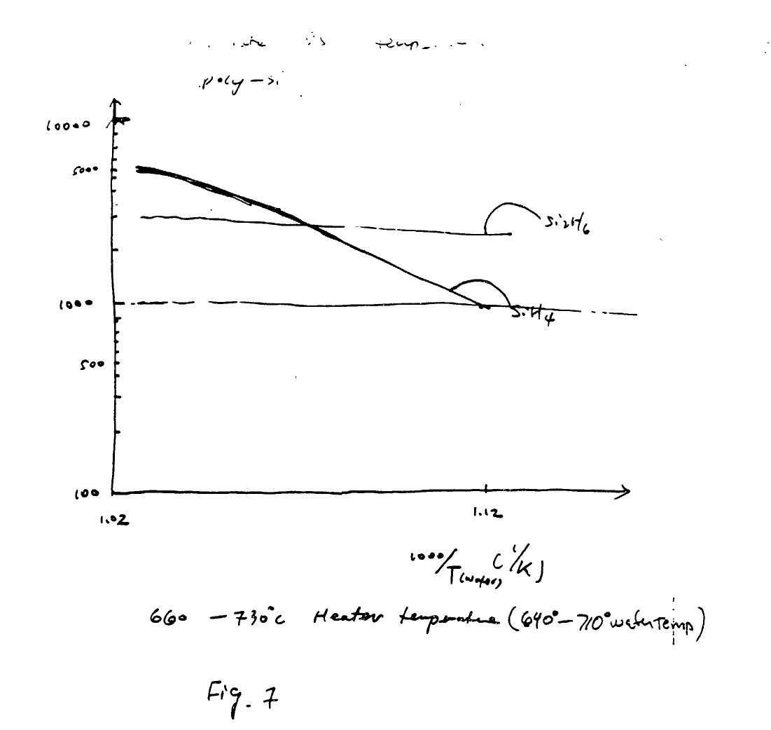

By utilizing a process gas having a silicon source gas and which provides a low reaction activation energy polycrystalline silicon films can be formed which are much less sensitive to temperature variation then silicon films formed with process gas having high reaction activation energies, such as those using silane (SiH₄). FIG. 7 is a logritmic plot which illustrates how the deposition rate of polycrystalline films using disilane and silane vary for wafer different temperatures. As can be seen by FIG. 7 the deposition rate for disilane at wafer temperature between 640-710° C. (heater temperature about 660-730° C.) the deposition rate is not significantly changed compared to a factor of 4-5 for monosilane (SiH₄).

When utilizing disilane (Si₂H₆), polycrystalline silicon films having either a columnar grain structure or a random grain structure can be formed by controlling the amount of hydrogen in the process gas mix. In some instances, a polycrystalline silicon film having only columnar grain structure is desired and in other instances, a polycrystalline silicon film having only random grain silicon is desired. For example, a polycrystalline silicon film having a complete random structure and small grain size can create a very smooth surface which can be useful in device processing. In other instances, such as in the fabrication of gates electrodes, it may be desirable to form a bi-layer silicon film having both a random grain crystalline structure portion and a columnar grain crystalline portion. In order to describe the methods of forming a columnar grain polycrystalline film and a polysilicon film with random grains, a method will be described in which a bi-layer silicon having both columnar grains and random grains is formed. It is to be appreciated that one can use the process taught forming columnar grain structure to form just a columnar grain film and one can use the process taught for forming a random grain microstructure to produce a film having only random grains. Additionally, although the formation of the polycrystalline silicon films will be described with respect to forming undoped silicon films. It is to be appreciated that doped polycrystalline silicon films can be formed by insitu doping by including a flow of approximately 25-100 sccm of 1% diluted arsine or phosphine for n type dopant and diborane for p type dopant.

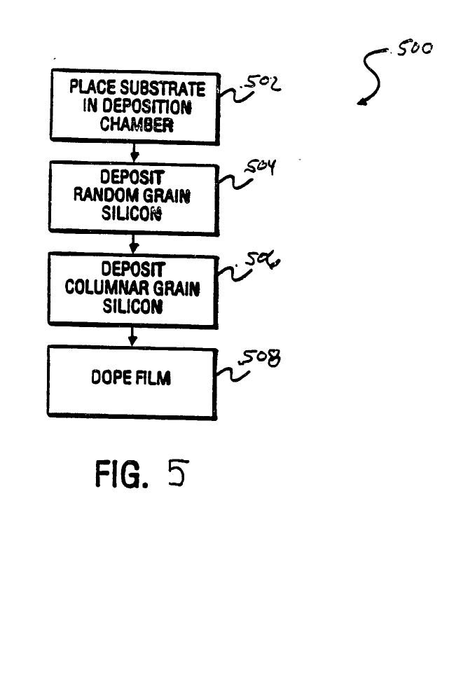

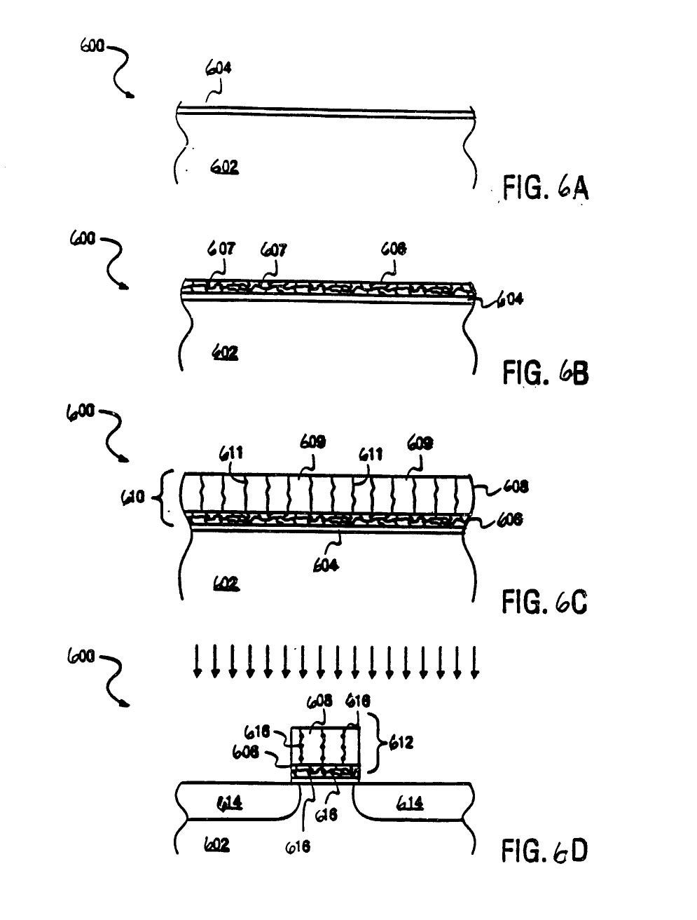

A method of forming a bi-layer polycrystalline silicon in accordance with the present invention, is set forth in the flow chart 500 in FIG. 5. The method of forming a bi-layer film will be illustrated and described in the process used to form a p type MOS transistor having a bi-layer silicon gate electrode as shown in FIGS. 6A-6D.

The first step in the method of the present invention as set forth in step 502 of flow chart 500 in FIG. 5, is to place a substrate or wafer on which the bi-layer silicon film is to be formed in a deposition reactor. In order to fabricate an MOS transistor with a bi-layer silicon film gate electrode, a substrate or wafer, such as substrate 600 as shown in FIG. 6A is provided. Substrate 600 includes a single crystalline silicon substrate 602 having a gate dielectric layer 604 formed thereon. The single crystalline silicon substrate will typically be slightly doped with p type impurities (e.g., boron) for NMOS device and slightly doped with n type dopants (e.g., arsenic or phosphorous) for PMOS device. The gate dielectric can be any suitable dielectric layer such as but not limited to silicon dioxide, silicon oxynitride, and nitrided oxides. Additionally, substrate 600 will typically include isolation regions (not shown) such as LOCOS or shallow trench (STI) regions to isolate the individual transistor formed in substrate 600.

Substrate 600 is placed in a chemical vapor deposition (CVD) reactor which is suitable for depositing the bi-layer silicon film of the present invention. An example of a suitable CVD apparatus is the resistively heated low pressure chemical vapor deposition reactor illustrated in FIGS. 1-3.

In an embodiment of the present invention, where a bi-layer polycrystalline silicon film is used to form a gate electrode, the random grain boundary polysilicon film 606 is formed directly onto gate dielectric 604 as shown in FIG. 6B. The lower polycrystalline silicon film has an average grain size between 50-500 Å and has a vertical dimension which is approximately the same as the horizontal dimension. The polycrystalline silicon film 606 has a crystal orientation which is dominated by the <111> direction.

In order to deposit a random grain boundary polysilicon film in an embodiment of the present invention, first the desired deposition pressure and temperature are obtained and stabilized in chamber 90. While achieving pressure and temperature stabilization, a stabilization gas such as N₂, He, Ar, or combinations thereof are fed into chamber 90. In a preferred embodiment of the present invention the flow and concentration of the dilution gas used in the random grain polysilicon deposition is used to achieve temperature and pressure stabilization. Using the dilution gas for stabilization enables the dilution gas flow and concentrations to stabilize prior to polysilicon deposition.

In an embodiment of the present invention the chamber is evacuated to a pressure between 50-350 Torr with 150-250 Torr being preferred and the heater temperature raised to between 690-730° C. and preferably between 700-710° C. while the dilution gas is fed into the chamber at a flow rate between 10-30 slm. According to the present invention the dilution gas consist of H₂ and an inert gas, such as but not limited to nitrogen (N₂), argon (Ar), and helium (He), and combinations thereof. For the purpose of the present invention an inert gas is a gas which is not consumed by or which does not interact with the reaction used to deposit the polysilicon film and does not interact with chamber components during polysilicon film deposition. In a preferred embodiment of the present invention the inert gas consist only of nitrogen (N₂). In an embodiment of the present invention H₂ comprises more than 8% and less than 35% by volume of the dilution gas mix with the dilution gas mix preferably having between 20-30% H₂ by volume.

In the present invention the dilution gas mix has a sufficient H₂/inert gas concentration ratio such that a subsequently deposited polysilicon film is dominated by the <111> crystal orientation as compared to the <220> crystal orientation. Additionally, the dilution gas mix has a sufficient H₂/inert gas concentration ratio so that the subsequently deposited polycrystalline silicon film has a random grain structure with an average grain size between 50-500 Å.

In an embodiment of the present invention the dilution gas mix is supplied into the chamber in two separate components. A first component of the dilution gas mix is fed through distribution port 20 in chamber lid 30. The first component consist of all the H₂ used in the dilution gas mix and a portion (typically about ⅔) of the inert gas used in the dilution gas mix. The second component of the dilution gas mix is fed into the lower portion of chamber 90 beneath heater 80 and consists of the remaining portion (typically about ⅓) of the inert gas used in the dilution gas mix. The purpose of providing some of the inert gas through the bottom chamber portion is to help prevent the polycrystalline silicon film from depositing on components in the lower portion of the chamber. In the embodiment of the present invention between 8-18 slm with about 9 slm being preferred of an inert gas and all of the hydrogen gas is fed through the top distribution plate while between 3-10 slm, with 4-6 slm being preferred, of the inert gas (preferably N₂) is fed into the bottom or lower portion of chamber 90.

Next, once the temperature, pressure, and gas flows have been stabilized a first process gas mix comprising disilane (Si₂H₆) and a dilution gas mix comprising H₂ and an inert gas is fed into chamber to deposit a random grain polycrystalline silicon film 606 on substrate 600 as shown in FIG. 6B. In the preferred embodiment of the present invention the silicon source gas is disilane (Si₂H₆) but can be other silicon source gases such as (Si₃H₈) so long as the process gas mix provides a reaction activation energy of less than 0.5 eV at a temperature less than 750° C. According to the preferred embodiment of the present invention between 20-300 sccm, with between 40-100 sccm being preferred, of disilane (Si₂H₆) is added to the dilution gas mix already flowing and stabilized during the temperature and pressure stabilization step. In this way during the deposition of random grain polysilicon, a first process gas mix comprising between 40-100 sccm of disilane (Si₂H₆) and between 10-30 slm of dilution gas mix comprising H₂ and an inert gas is fed into the chamber while the pressure in chamber is maintained between 150-350 Torr and the temperature of susceptor 5 is maintained between 690-730° C. (It is to be appreciated that in the LPCVD reactor the temperature of the substrate or wafer 600 is typically about 20-30° cooler than the measured temperature of susceptor 5). In the preferred embodiment of the present invention the silicon source gas is added to the first component (upper component) of the dilution gas mix and flows into chamber 90 through inlet port 40.

The thermal energy from susceptor 5 and wafer 600 causes the silicon source gas to thermally decompose and deposit a random silicon polysilicon film 606 on gate dielectric as shown in FIG. 6B. In an embodiment of the present invention only thermal energy is used to decompose the silicon source gas without the aid of additional energy sources such as plasma or photon enhancement.

As the first process gas mix is fed into chamber 90, the silicon source gas decomposes to provide silicon atoms which in turn form a random grain polycrystalline silicon film 606 on dielectric layer 604. It is to be appreciated that H₂ is a reaction product of the decomposition of disilane (Si₂H₆). By adding a suitable amount of H₂ in the process gas mix the decomposition of disilane (Si₂H₆) is slowed which enables a polycrystalline silicon film 606 to be formed with small and random grains 607. In the present invention the volume percent of H₂ in the dilution gas is used to manipulate the silicon resource reaction across the wafer. By having H₂ comprise between 8-50% of the dilution gas mix random grains having an average grain size between 50-500 Å can be formed. Additionally, by including a sufficient amount of H₂ in the dilution gas mix a random grain polycrystalline silicon film 606 which is dominated by the <111> crystal orientation, as opposed to the <220> crystal orientation is formed.

According to the present invention the deposition pressure, temperature, and process gas flow rates and concentration are chosen so that a polysilicon film is deposited at a rate between 1500-5000 Å per minute with between 2000-3000 Å per minute being preferred. The process gas mix is continually fed into chamber 90 until a polysilicon film 606 of a desired thickness is formed. In an embodiment of the present invention, random grain polycrystalline silicon film 606 is used as a diffusion barrier to prevent subsequently implanted dopants, such as boron, from passing through the film and entering the dielectric layer 604. In such a case the random grain polycrystalline silicon film 606 is formed sufficiently thick to prevent boron from substantially diffusing through the film and into the gate dielectric 604 during the subsequent thermal annealing step used to activate the dopants. When generating a diffusion barrier for gate electrode applications a polysilicon film 606 having a thickness between 200-500 Å has been found suitable.

Next, as set forth in block 506 of flow chart 500 as shown in FIG. 5, after random grain polysilicon film 606 is formed, a polycrystalline silicon film having columnar grains is formed directly onto the random grain boundary polysilicon film 606 as shown in FIG. 6C. The grains 609 have a vertical dimension to horizontal dimension of at least 2:1 and preferably at least 4:1.

A columnar grain silicon film can be formed by providing a second process gas mix comprising disilane (Si₂H₆) and a dilution gas into the chamber while maintaining a pressure between 150-350 torr and heater temperature between 690-730° C. A columnar grain silicon film can be achieved by controlling the amount of H₂ (volume percent) included in the dilution gas of the second process gas mix. A suitable columnar grain silicon film 608 as shown in FIG. 6C can be formed by flowing into deposition chamber 90 a second process gas mix comprising a disilane (Si₂H₆) and a dilution gas wherein the dilution gas comprises an inert gas (e.g., N₂, Ar, and He) and hydrogen gas (H₂) wherein H₂ comprises less than 8% by volume of the dilution gas mix and preferably less than 5% by volume of the dilution gas. In an embodiment of the present invention, the columnar grain silicon film 608 is formed with a second process gas mix consisting only of a disilane (Si₂H₆) and a dilution gas consisting only of an inert gas and no H₂. A polycrystalline silicon film 608 having columnar grains can be formed by flowing a second process gas mix comprising between 50-150 sccm of disilane (Si₂H₆) and between 10-30 slm of a dilution gas mix comprising less than 5% H₂ by volume and an inert gas while the pressure in chamber 90 is maintained between 150-350 torr and the temperature of the susceptor 5 maintained between 690-730° C.

Like the first process gas mix for forming the random grain silicon film, the second process gas mix for the columnar grain silicon has two components wherein the first component enters through distribution port 20 and contains about ⅔ of the dilution gas and all of the silicon containing gas and wherein the second component consist of the remaining ⅓ of the dilution gas and is fed into the lower portion of the chamber. If H₂ is included during the formation of the columnar grain polycrystalline film it is mixed with the inert gas prior to entering the chamber and enters the chamber with the first component through distribution port 20 in chamber lid 30.

In a preferred embodiment of the present invention, the polycrystalline silicon film 608 with columnar grain microstructure is formed “insitu” with or in the same chamber (i.e., chamber 90) as the random grain polysilicon film 604. In this way, polysilicon film 604 is not exposed to an oxidizing ambient or to contaminants before the formation of columnar polysilicon film 608 is formed thereby enabling a clean interface to be achieved between the films. In an embodiment of the present invention, when polysilicon film 606 and 608 are formed insitu, the deposition chamber is purged with an inert gas for approximately 5 seconds to insure that all H₂ is removed from the chamber prior to deposition of the columnar grain polysilicon film 608. The purge can occur at the same deposition temperature and pressure and with the same inert gas flows as used to deposit the polycrystalline films. In this way, a fast, efficient and continuous process can be used to form the bi-layers silicon film 610.

Columnar grain silicon film 608 is formed until the desired thickness of silicon film 608 is obtained. In an embodiment of the present invention, where the bi-layer silicon film is used to form a gate electrode, columnar grain silicon film 608 can be formed to a thickness between 1500-1800 Å to achieve a total film thickness of bi-layer silicon film 610 of approximately 2000 Å. It is to be appreciated, however, that the thickness of columnar grain silicon film 608 can be made to any thickness desired for any specific application. After columnar grain polysilicon film 608 has been completed, the flow of the second process gas mix is stopped and heater lowered from the process position to the load position and wafer 600 removed from chamber 90. At this time, the formation of a bi-layer silicon in accordance with an embodiment of the present invention is complete.

Next, as set forth in step 508 of flow chart 500 of FIG. 5, the bi-layer silicon film can be doped to a desired conductivity type and level, if desired. Bi-layer polysilicon film 610 can be doped by well-known ion-implantation and thermal anneal steps. The bi-layer silicon film 610 can be doped while in blanket form over substrate 600 (i.e., prior to patterning) or after patterning into, for example, interconnects or electrodes. When forming an MOS transistor, it is preferable to ion-implant the bi-layer polysilicon film after it has been patterned with well-known photolithography and etching techniques into gate electrode 612 as shown in FIG. 6D. In this way, the ion-implantation step used to counter dope the single crystalline silicon substrate to form source/drain regions 614. The implant can also be used to dope the gate electrode and thereby reduces resistivity.

When forming a PMOS transistor, p type impurities 616 (e.g., boron) are implanted into single crystalline silicon substrate 602 in alignment with the outside edges of gate electrode 612 to form source/drain regions 614 as well as into bi-layer polysilicon gate electrode 612. Boron can be implanted utilizing BF3 as a source at a dose in the amount of 1-5×10¹⁶ atoms/cm² to achieve a dopant density on the order of 1×10²⁰ atoms/cm³ (If an n type device is to be formed n type impurities such as arsenic or phosphorous or implanted into a p type single crystalline substrate). The ion-implantation step generally places dopants into the columnar grain polysilicon film 608 of bi-layer polysilicon film 610. A subsequent thermal anneal is used to drive and activate the dopants deep into the columnar grain silicon film as well as into the random grain silicon film 606 as shown in FIG. 6D. The microstructure of the columnar grain polysilicon film 608 enables the fast and uniform diffusion of dopants throughout the film via the long columnar grain boundaries 611. Dopants 616 reach the random grain silicon film 606 and diffuse throughout the many grain boundaries of the random grain silicon film. Because of the many grain boundaries, the dopants diffuse less in the vertical direction (as compared to the columnar grain silicon) and so the random grain boundary provides a blocking effect which prevents the dopants from penetrating into the underlying gate dielectric layer 604. This especially useful when the dopant impurity is boron. In an embodiment of the present invention, the random grain polysilicon film 606 is formed to a thickness sufficient to block boron penetration into the underlying gate oxide during the thermal anneal used to drive and activate the dopants. The dopants can be driven and activated with any well-known process, such as for example, a rapid thermal process at a temperature between 800-1100° C. for a period of time between 30-120 seconds in an ambient comprising for example 10% O₂ in 90% N₂. Alternatively, the dopants can be driven and activated by the next high temperature process step in the integrated circuit fabrication process.

If desired, silicide or other metal layers can be formed on the top of gate electrode 612 as well as onto source/drain regions 614 to further reduce the parasitic resistance of the device. At this point, the fabrication of a MOS transistor having a bi-layer polycrystalline silicon gate electrode is complete.

Silicon Nitride Films

In an embodiment of the present invention, a process gas mix having a silicon source gas and which provides a low reaction activation energy is used to deposit a silicon nitride (Si₃N₄) film. In a preferred embodiment of the present invention, a silicon nitride film is formed by utilizing disilane as the silicon precursor. A silicon nitride film deposition can be achieved by using a process gas mix comprising disilane (Si₂H₆) and a nitrogen containing gas, such as ammonia (NH₃). Utilizing disilane as the silicon source gas a silicon nitride film can be deposited by thermal CVD for wafer temperatures between 480-730° C. and at deposition pressure of between 5-350 torr.

A suitable silicon nitride film can be formed at a temperature between 600-750° C. at a pressure between 100-300 torr with a process gas mix comprising between 10-30 sccm of Si₂H₆, between 2000-6000 sccm of NH₃ and between 5000-15000 sccm of N₂.

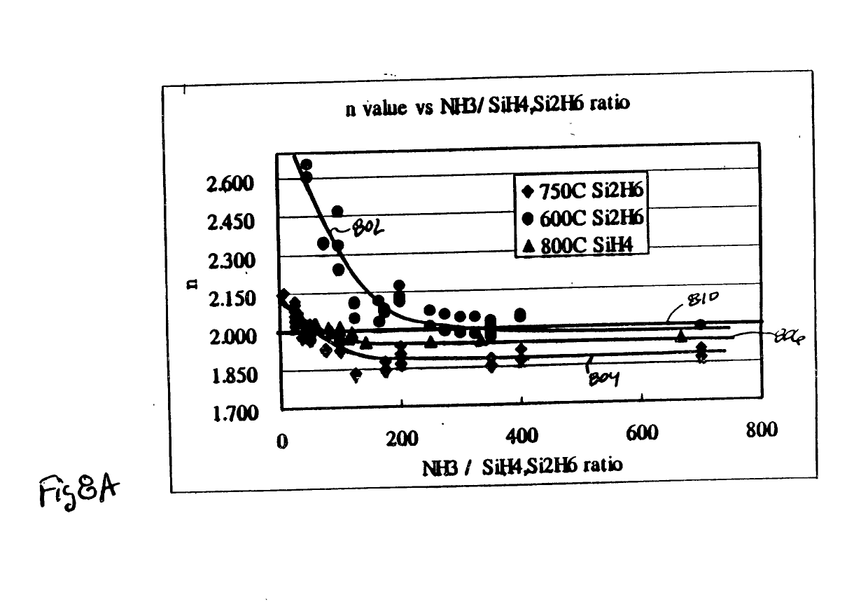

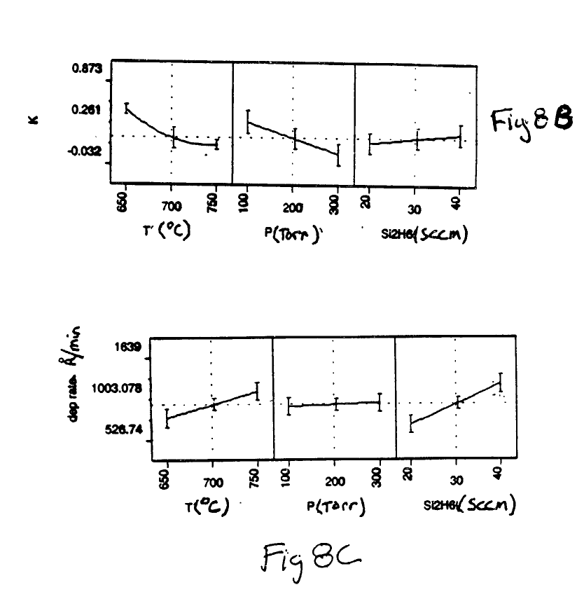

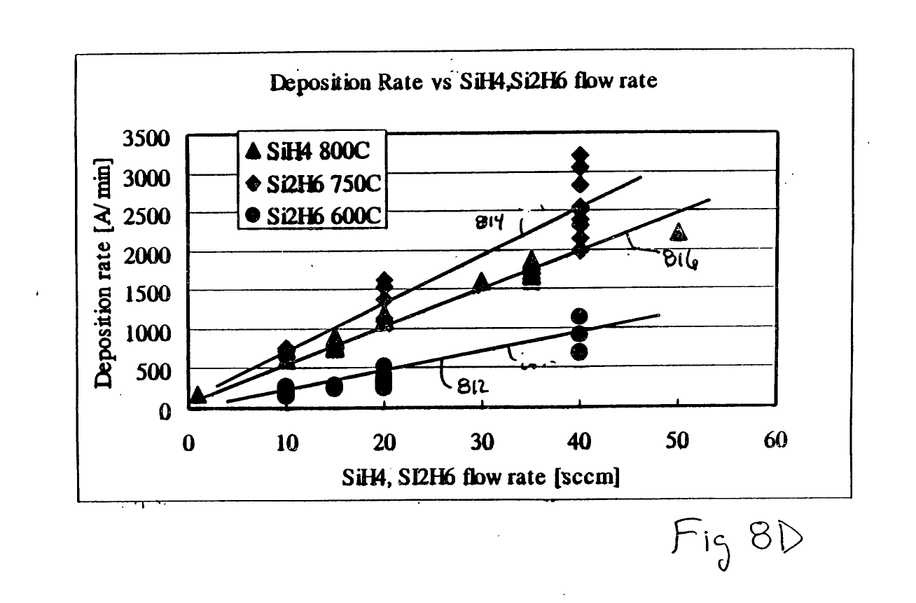

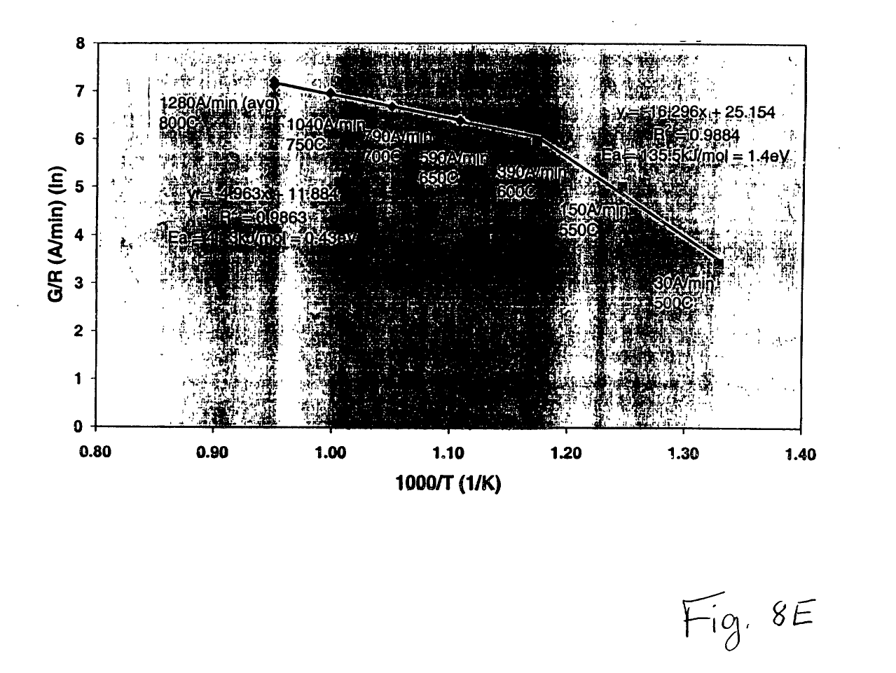

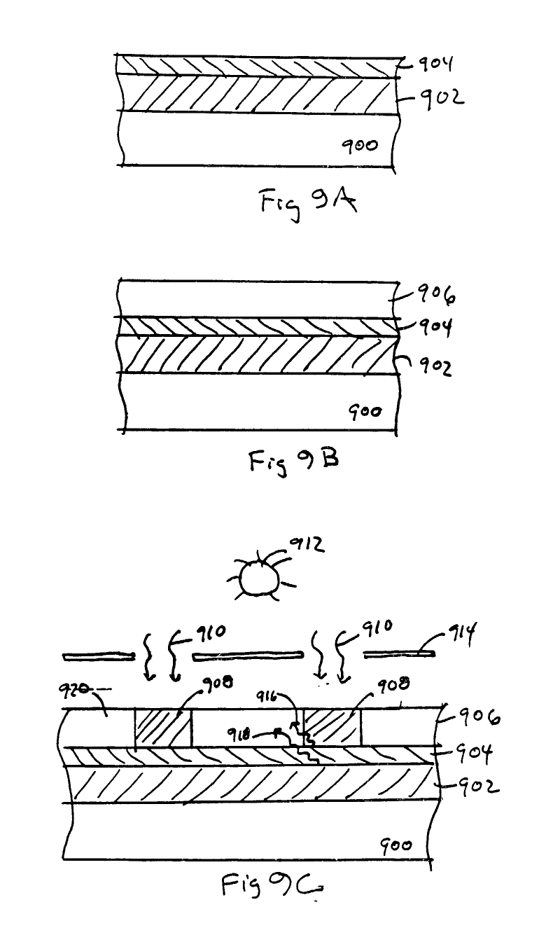

By utilizing a process gas mix which provides a low reaction activation energy, less than 0.5 eV at a temperature less than 750° C. to form a silicon nitride film, the deposition rate for a given set of process conditions is substantially higher than for a process gas mix having a high reaction activation energy such as one that utilizes silane (SiH₄). FIG. 8D illustrates two plots on how the deposition rates of silicon nitride film with process gases utilizing different amounts of disilane (Si₂H₆) vary for films formed at 600° C. (812) and 750° C. (814). Also shown in FIG. 8D, is a plot 816 that depicts the deposition rates of silicon nitride film formed utilizing silane (SiH₄) at 800° C.

FIG. 8E is a graph which shows how the deposition rate of a silicon nitride film formed with disilane (Si₂H₆) varies for different temperatures. As is evident from the graph of FIG. 8E the deposition rate for silicon nitride utilizing disilane is insensitive to temperature at temperatures greater than 550° C.

By utilizing disilane and the LPCVD chamber shown in FIGS. 1-3, silicon nitride films can be formed having less than 2% (thickness range/2×average thickness) film thickness uniformity at a high deposition rate (greater than 1000 Å per minute) and at low deposition temperatures. By utilizing disilane (Si₂H₆) as the silicon source gas, process recipes can be tuned to form silicon nitride films with different film composition and properties, such as films with different Si/N ratios, films with different refractive indicies (RI), films with different extinction coefficient (k), and films with different value of (n). (Refractive index (RI)=n(γ)+ik(γ) where (n) is the real part of the refractive index, and (k) is the imaginery part of the refractive index or the extinction coefficient and γ is the wavelength of the incident radiation.) The refractive index (RI) of a silicon nitride film can be tuned or adjusted by tuning the value of (n) and (k). By utilizing disilane as the silicon source gas in the deposition of a silicon nitride film, extinction coefficient (k) values between 0.001-0.65 and (n) values between 1.8%-2.6% can be achieved. Additionally, the hydrogen concentration in the film can be controlled by controlling the deposition rate and temperature.

Illustrated in FIG. 8A is an empirically determined plot which shows how the (n) value of the refractive index (RI) of a silicon nitride film can be tuned by controlling the ammonia (NH₃)/disilane (Si₂H₆) ratio. Plot 802 shows how the value of n changes for a silicon nitride film deposited at a temperature of 750° C. for different NH₃/Si₂H₆ ratios while plot 804 shows how the value of (n) changes for a silicon nitride film deposited at a temperature of 600° C. for different NH₃/Si₂H₆ ratios. Also shown in FIG. 8A is a plot 806 which illustrates how the value of n changes for a silicon nitride film formed at a relatively high temperature of 800° C. for different NH₃/silane (SiH₄) ratios. As is evident with FIG. 8A a wide process window is obtained enabling the formation of a silicon nitride films having a wide range of different values of (n). For example, utilizing disilane one can produce a silicon nitride film having a value of (n) between 1.8 and 2.6. As shown in FIG. 8A, a silicon nitride film formed with siline (SiH₄) has a small range of (n) values that can be produced. Additionally, by utilizing disilane as the silicon source gas one can produce silicon nitride films having (n) values greater than 2.15.

FIG. 8B shows how the values for the extinction coefficient (k) can be tuned by controlling the temperature, pressure, and disilane flow. By utilizing disilane as the silicon source gas the extinction coefficient (k) can be easily tuned between 0.001-0.65. When silicon nitride film is used as a anti-reflective coating a extinction coefficient of between 0.3-0.5 is typically desired.

FIG. 8C shows how the deposition rate of silicon nitride film formed with disilane varies for different temperatures, pressures, and disilane flow rates.

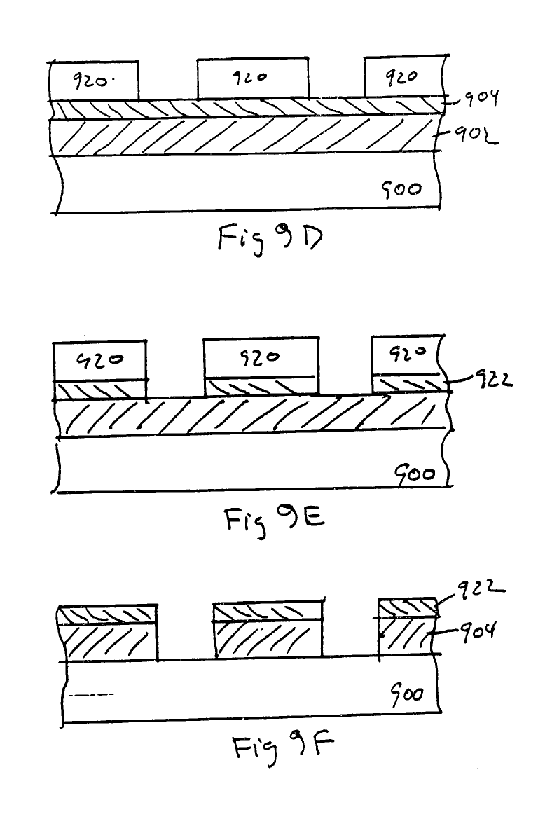

Because a silicon nitride film formed with disilane has a wide window to control the (n) and (k) values of the film, they are ideal for use as anti-reflective coatings. This is especially useful when the silicon nitride film is also used as a hard mask in the fabrication of integrated circuits because the silicon nitride hard mask can then also act as the anti reflective coating thereby eliminating the need for a separate ARC layer. Hard masks are typically used to provide etching selectivity to an underlying film, and to provide polishing stops during chemical mechanical polishing processes. For example, illustrated in FIGS. 9A-9F, is a method of using a silicon nitride film deposited from disilane as a hard mask and an anti-reflective coating. A film 902 to be patterned, such as a polysilicon film on a metal film such as tungsten, is blanket deposited over the substrate 900 as is well-known in the art. A silicon nitride hard mask layer 904 is then deposited using disilane directly onto the film 902 to be patterned.

Next, as shown in FIG. 9B, a photoresist layer 906, typically negative photoresist, is formed directly onto the hard mask 904 without the need for an anti-reflective coating. It is to be noted that whenever disilane is used to form a silicon nitride film 906, the surface of the silicon nitride film 906 can be hydrogen (H) terminated. Unfortunately, hydrogen termination can cause photoresist poisoning at the photoresist silicon nitride interface due to the hydrogen termination. Thus, according to an embodiment of the present invention, prior to the formation of photoresist layer 706, the silicon nitride film is given an N₂O treatment to cure the hydrogen termination. The disilane base silicon nitride film can be suitably treated by exposing the silicon nitride film 904 to an ambient created by flowing N₂O into a single wafer cold wall rapid thermal reactor, such as the Applied Materials RTP Centura, while heating the substrate to a temperature between 600-1100° C. for a period of time between 1-60 seconds. Alternatively, the silicon nitride film can be treated with N₂O in a furnace heated to a temperature between 600-1100° C. The N₂O treatment enables a photoresist layer to be formed directly onto silicon nitride film 904 without the concern of photoresist poisoning.

Next, as shown in FIG. 9C, the photoresist layer 906 is imaged by exposing selective portions 908 to radiation 910 from a source, such as a lamp 912 through a mask or reticle 914 which contains the patterned desired to be formed in the film 902. During exposure only those portions of the photoresist not covered by a mask are exposed to radiation. By controlling the (n) and (k) values of the deposited silicon nitride film, the silicon nitride film can cause the phase shift cancellation of any reflected light. That is, by controlling and choosing the n and k values of the silicon nitride film as well as the thickness of the silicon nitride film, radiation 916 reflected from the top surface of silicon nitride film 904 can be made to phase shift cancel radiation reflected from the top surface of film 902. By canceling the reflected radiation, stray reflected radiation cannot expose adjacent areas 920 of photoresist layer 906 which are not to be exposed thereby enabling the precise imaging of the image in mask 914 into photoresist layer 906.

Next, as well-known in the art and as shown in FIG. 9D, photoresist layer is developed to remove those portions 908 exposed by light radiation and leaves those portions 920 unexposed by radiation. Such a step creates a photoresist mask having the image formed in mask 914.

Next, as shown in FIG. 9E, silicon nitride layer 904 is anisotropically etched to remove portion of silicon nitride film 904 not covered by photoresist 920 and thereby form a silicon nitride hard mask 922.

Next, as shown in FIG. 9F, the photoresist layer can be removed and the film 902 to be patterned can be etched in alignment with the silicon nitride hard mask 922. At times it is desirable to be able to selectively or preferentially etch the silicon nitride layer 904 with respect to the film to be patterned 902. By utilizing a disilane silicon source gas to produce the silicon nitride layer, a wide range of silicon to nitrogen Si/N silicon nitride film can be formed. By choosing the correct ratio of silicon to nitrogen Si/N, the etch rate of the silicon nitride film can be tuned to provide the selectivity with respect to the underlying film 902. For example, a silicon rich silicon nitride film can provide wet etch rate properties and high extension coefficient values to enable the silicon nitride film to be utilized in ARC lithographic process.

Silicon Oxide/Silicon Oxynitride

In an embodiment of the present invention, uniform silicon oxide films, such as silicon dioxide and silicon oxynitride, can be formed by thermal chemical vapor deposition in a single wafer resistively heated cold wall reactor utilizing a process gas mix comprising a silicon source gas and having a low reaction activation energy of less than 0.5 eV at a temperature between 550° C.-750° C. A uniform silicon oxide film can be formed by thermal chemical vapor deposition utilizing a process gas mix comprising disilane and an oxygen precursor, such as N₂O, and a disilane/N₂O flow ratio between 1:50 to 1:10,000 respectively while maintaining a deposition pressure of between 5 torr-350 torr and a deposition temperature of between 530-730° C. Disilane can be fed into the deposition chamber at a rate of between 1 sccm-75 sccm while the oxygen precursor is fed into the deposition chamber at a rate between 0.5 slm-10 slm. If a silicon oxynitride film is desired, a nitrogen source gas, such as ammonia (NH₃), can also be included into the process gas mix at a rate of between 0.1-6 slm. Such a process can form a uniform film having a thickness uniformity of <2% (thickness range/2×average range) across the surface of the wafer at high deposition rates of between 50 Å per minuet-2000 Å per minute.

It is to be appreciated that all process flows provided in the description of the present invention are for 200 mm process in a single wafer chamber having a 5-6 liter volume.

Composite Film Stack

In an embodiment of the present invention, a process gas mix having a silicon source gas and which provides a low reaction activation energy is used form each silicon containing layer of a composite film stack. In a preferred embodiment of the present invention disilane is used as the silicon source gas in the thermal chemical vapor deposition of each silicon containing film of a composite film stack. By utilizing disilane to deposit the various silicon containing films, the deposition process of each film is less temperature sensitive enabling each of the films to be deposited, at or almost at, the same deposition temperature and still obtain highly uniform films. The ability to form each film at the same deposition temperature is very valuable especially when utilizing a temperature control device, such as a resistivly heated ceramic heater 80 which has a low or slow rate of temperature change, such as less than 1.0° C. per second. By being able to form each of the individual films at the same deposition temperature, wafer throughput is dramatically increased.

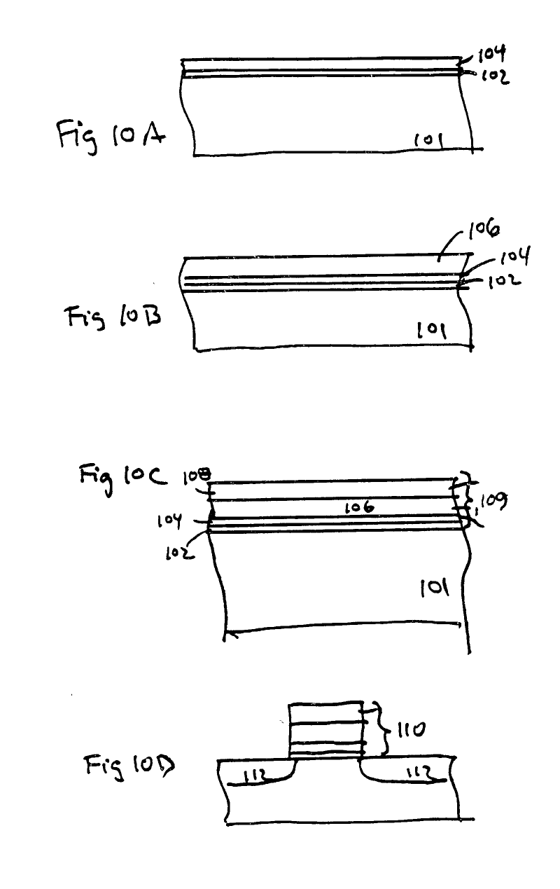

FIGS. 10A-10D illustrate a method of forming a composite film stack where each film is formed at essentially the same deposition temperature as a previous silicon containing film. FIGS. 10A-10D illustrate a method of forming a composite film stack for a gate electrode with an MOS transistor. It is to be appreciated that the teachings can be utilized to form a wide variety of stacks of different silicon containing films. In a method of forming a composite film stack for a gate electrode, a undoped amorphous silicon film 104 is formed directly onto a gate dielectric layer 102 which is formed on a silicon monocrystalline substrate 101. Amorphous silicon film is formed utilizing a deposition gas comprising disilane while heating the substrate to first deposition temperature which is between 550-700° C.

Next, as shown in FIG. 10B, a silicon germanium alloy film (SiGe) 106 is formed directly onto the amorphous silicon film. The silicon germanium alloy film is formed with a deposition gas comprising disilane and germane (GeH₄) at the same temperature utilized to deposit silicon film 104. A silicon germanium film having a thickness between 500-1000 Å can be formed. An alloy having a ratio of silicon to germanium (Ge:Si) up to 1:1 can be formed. The Ge:Si ratio can be used to set the work function of the gate electrode. Next, a silicon film 108 is formed directly onto silicon germanium alloy film 106 utilizing disilane as a silicon source gas and the same deposition temperature utilized to form silicon germanium film 104.

Next, as shown in FIG. 10D, well-known silicon processing techniques can be utilized to pattern the composite film stack 109 into composite gate electrode 110, and then well-known dopant techniques, such as ion-implantation may be utilized to form a pair of source/drain regions 112 into the monocrystalline substrate 101.

Referring back to FIG. 1, LPCVD chamber 100 includes a processor/controller 700 and a memory 702, such as a hard disk drive. The processor/controller 700 includes a single board (SBC) analog and digital input/output boards, interface boards and stepper motor controller board. Process/controller 700 controls all activity of the LPCVD chamber. The system controller executes system control software, which is a computer program stored in a computer readable medium such as memory 702. The computer program includes sets of instructions that dictate the timing, mixture of gases, chamber pressure, heater temperature, power supply, susceptor position, and other parameters of the silicon containing film deposition process of the present invention. The computer program code can be written in any conventional computer readable programming language, such as 68000 assembly language, C, C++, Pascal, Fortran, or others. Subroutines for carrying out process gas mixing, pressure control, and heater control are stored within memory 702. Also stored in memory 702 are process parameters necessary to form a silicon containing film as described above. Thus, according to the present invention LPCVD chamber 100 includes in memory 702 instructions and process parameters for providing a process gas mix comprising a silicon source gas and which provides a reaction activation energy of less than 0.5 eV at a temperature less than 750° C. and above 550° C. into chamber 90 to deposit a silicon containing film in accordance with the present invention.

We claim:

1. A method of forming a uniform silicon containing film comprising:
heating a wafer in a chamber such that said wafer has a greater than 5° C. temperature variation across said wafer;
providing a process gas mix comprising a silicon source and which provides a reaction activation energy of less than 0.5 eV at a temperature less than 750° C. and above 550° C.; and
depositing said silicon containing film from said deposition gas mix.

2. The method of claim 1 wherein said process gas has a reaction activation energy of less than 0.2 eV.

3. The method of claim 1 wherein said silicon containing gas is disilane (Si₂H₆).

4. The method of claim 1 wherein said silicon source gas is Si₃H₈.

5. The method of claim 1 wherein said silicon containing film is silicon nitride.

6. The method of claim 1 wherein said silicon containing film is amorphous or polycrystalline silicon.

7. The method of claim 6 wherein said silicon containing film is doped polycrystalline or amorphous silicon.

8. The method of claim 1 wherein said silicon containing film is a silicon germanium alloy.

9. The method of claim 1 wherein wafer has a temperature variation of greater than 10° C. during said deposition.

10. A method of forming a composite film having multiple silicon containing films comprising:
placing a wafer in a chamber;
heating said substrate in said chamber to a deposition temperature;
forming a first silicon containing film on said wafer by providing a first process gas mix having silicon source gas and which provides a reaction activation energy of less than 0.5 eV at a temperature between 750° C.-550° C. into said deposition chamber while heating said wafer to said deposition temperature; and
forming a second silicon containing film on said first silicon film wherein said second silicon film is formed by providing a second process gas mix comprising a silicon source gas and which provides a reaction activation energy of less than 0.5 eV at a temperature between 750° C.-550° C. while heating said wafer to said deposition temperature, and wherein said second silicon containing film is different than said first silicon containing film.

11. The method of claim 10 further comprising forming a third silicon containing film on said second silicon containing film wherein said third silicon containing film is formed by providing a third process gas mix having silicon source gas and which provides an activation energy of less than 0.5 eV at a temperature between 750° C.-550° C. while heating said wafer to said deposition temperature, wherein said third silicon containing film is different than said second silicon containing film.

12. The method of claim 11 wherein said first silicon source gas and said second silicon source gas and third silicon source gas are disilane (Si₂H₆).

13. The method of claim 11 wherein said first silicon containing film is undoped amorphous silicon.

14. The method of claim 11 wherein said second silicon containing film is a silicon germanium alloy.

15. The method of claim 12 wherein said third silicon containing film is a polycrystalline or amorphous silicon film.

16. The method of claim 11 wherein said wafer is heated to said deposition temperature with a resistive heater having a change of temperature rate of less than 1.0° C. per second.

17. A method of patterning a film comprising:
forming a film over a substrate;
forming a silicon nitride film on said film, wherein said silicon nitride film is deposited by thermal chemical vapor deposition utilizing a process gas mix comprising a silicon source gas and a nitrogen source gas wherein said process gas mix provides a reaction activation energy of less than 0.5 eV at a temperature between 750° C. and 550° C.;
forming a photoresist layer directly on said silicon nitride films; and
exposing said photoresist layer to a radiation through a mask in order to image said photoresist film.

18. The method of claim 17 wherein said process gas mix provides a reaction activation energy of less than 0.3 eV.

19. The method of claim 17 wherein said silicon source gas is disilane (Si₂H₆).

20. The method of claim 17 wherein said silicon source is Si₃H₈.

21. The method of claim 17 further comprising the step of treating said silicon nitride film to avoid photoresist poisoning at the photoresist/silicon nitride interface due to a hydrogen terminated silicon nitride surface.

22. The method of claim 17 further comprising the step of treating said silicon nitride film with an ambient comprising N₂O at a temperature between 600-1100° C. prior to forming said photoresist layer.

23. The method of claim 17 wherein said silicon film has a (n) value between 1.9 to 2.6.

24. The method claim 17 wherein said silicon nitride has a (n) value greater than 2.15.

25. The method of claim 17 wherein said silicon nitride film has an extinction coefficient (k) between 0.001-0.65.

26. A method of patterning a film comprising:
forming a film over a substrate;
forming a nitride layer on said film, wherein said nitride layer is deposited by thermal chemical vapor deposition utilizing a process gas mix comprising disilane and ammonia;
treating said silicon nitride film with an N₂O ambient at a temperature between 600-1100° C.; and
forming a photoresist layer directly onto said nitride layer.

27. The method of claim 26 wherein said silicon nitride film is treated in a rapid thermal processor.

28. The method of claim 26 wherein said silicon nitride film is treated in a furnace.
